(19) United States
(12) Patent Application Publication
(10) Pub. No.: US 2025/0372512 A1
(43) Pub. Date: Dec. 4, 2025

(54) MAGNETORESISTIVE RANDOM ACCESS MEMORY BEOL STRUCTURE IMPROVEMENT FOR PROCESS HEALTHY AND YIELD INCREASE

(71) Applicant: United Microelectronics Corp., Hsinchu (TW)

(72) Inventors: Ching Yi Chen, Kaohsiung City (TW); Po Kai Hsu, Tainan City (TW)

(73) Assignee: United Microelectronics Corp., Hsinchu (TW)

(21) Appl. No.: 18/751,344

(22) Filed: Jun. 24, 2024

(30) Foreign Application Priority Data
May 28, 2024 (TW) 113119597

(51) Int. Cl. H01L 23/528; H01L 23/522; H10B 61/00; H10N 50/01; H10N 50/10

(52) U.S. Cl. CPC H01L 23/5283; H01L 23/5226; H10B 61/00; H10N 50/01; H10N 50/10

(57) ABSTRACT

A magnetoresistive random access memory includes: a lower metal layer and a lower dielectric layer, disposed on a semiconductor substrate, and the lower metal layer disposed in the lower dielectric layer; a dielectric layer, disposed on the lower dielectric layer and the lower metal layer; a via plug, a magnetic tunnel junction and an additional metal layer, disposed in the dielectric layer, wherein the via plug is electrically connected to the lower metal layer, the magnetic tunnel junction is disposed on the via plug and the additional metal layer is disposed on the magnetic tunnel junction; an upper dielectric layer, disposed on the dielectric layer and the additional metal layer; and an upper via plug and an upper metal layer, disposed in the upper dielectric layer, wherein the upper via plug is electrically connected to the additional metal layer.

### CROSS-REFERENCE TO RELATED APPLICATION

This application claims the priority benefit of Taiwan application serial no. 113119597, filed on May 28, 2024. The entirety of the above-mentioned patent application is hereby incorporated by reference herein and made a part of this specification.

### BACKGROUND

### Technical Field

The disclosure relates to a magnetoresistive random access memory, and in particular relates to a magnetoresistive random access memory and a forming method thereof.

### Description of Related Art

Magnetoresistive random access memory (MRAM) is a type of non-volatile memory that has the advantages of high access speed, low power consumption, low latency, high scalability, and high endurance for read and write operations. Additionally, since this memory is implemented in the back end of line (BEOL) processes, it has minimal impact on the front end of line (FEOL) processes. Consequently, it is readily integrable with the manufacturing processes of other semiconductor components, forming a multifunctional and highly efficient integrated circuit.

However, in the BEOL processes of integrated circuits, including MRAM and other semiconductor devices, the required via depths for the via plugs between MRAM and other semiconductor devices vary. This discrepancy results in uneven etch profiles after etching, and in some cases, excessive etching may cause a penetrated region (open). These process-related issues negatively impact the overall electrical characteristics and yield of integrated circuits, including MRAM.

### SUMMARY

A magnetoresistive random access memory and a forming method thereof are provided in the disclosure to solve the problem of, in the BEOL processes of integrated circuits, including MRAM and other semiconductor devices, the required via depths for the via plugs between MRAM and other semiconductor devices vary. This discrepancy results in uneven etch profiles after etching, and in some cases, excessive etching may cause a penetrated region (open).

A magnetoresistive random access memory and a forming method thereof are provided in the disclosure to eliminate electrical problems caused by manufacturing process problems and improve the yield rate.

A magnetoresistive random access memory includes the following components. A lower metal layer and a lower dielectric layer are disposed on a semiconductor substrate, and the lower metal layer is disposed in the lower dielectric layer. A dielectric layer is disposed on the lower dielectric layer and the lower metal layer. A via plug, a magnetic tunnel junction and an additional metal layer are disposed in the dielectric layer, wherein the via plug is electrically connected to the lower metal layer. The magnetic tunnel junction is disposed on the via plug and the additional metal layer is disposed on the magnetic tunnel junction. An upper dielectric layer is disposed on the dielectric layer and the additional metal layer. An upper via plug and an upper metal layer are disposed in the upper dielectric layer, wherein the upper via plug is electrically connected to the additional metal layer.

In an embodiment of the disclosure, an upper surface of the additional metal layer is coplanar with an upper surface of the dielectric layer, and a lower surface of the via plug is coplanar with a lower surface of the dielectric layer.

In an embodiment of the disclosure, the additional metal layer is a bit line.

In an embodiment of the disclosure, the additional metal layer is a trapezoid with a wide top and a narrow bottom.

In an embodiment of the disclosure, a thickness of the additional metal layer is 550 angstroms to 600 angstroms.

A forming method of a magnetoresistive random access memory includes the following operation. A lower metal layer and a lower dielectric layer are formed on a semiconductor substrate. The lower metal layer is disposed in the lower dielectric layer. A via plug, a magnetic tunnel junction, and an additional metal layer are formed on the lower metal layer in sequence. The via plug is electrically connected to the lower metal layer. The magnetic tunnel junction is disposed on the via plug, and the additional metal layer is disposed on the magnetic tunnel junction. A dielectric layer is formed on the lower dielectric layer and the lower metal layer, and the via plug, the magnetic tunnel junction, and the additional metal layer are covered. The dielectric layer is etched to expose an upper surface of the additional metal layer. An upper dielectric layer is formed on the dielectric layer and the additional metal layer. An upper via plug and an upper metal layer are formed in the upper dielectric layer. The upper via plug is electrically connected to the additional metal layer.

In an embodiment of the disclosure, the upper surface of the additional metal layer is coplanar with an upper surface of the dielectric layer, and a lower surface of the via plug is coplanar with a lower surface of the dielectric layer.

In an embodiment of the disclosure, the additional metal layer is a bit line.

In an embodiment of the disclosure, the additional metal layer is a trapezoid with a wide top and a narrow bottom.

In an embodiment of the disclosure, a thickness of the additional metal layer is 550 angstroms to 600 angstroms.

A magnetoresistive random access memory includes the following components. A lower metal layer and a lower dielectric layer are disposed on a semiconductor substrate, and the lower metal layer is disposed in the lower dielectric layer. A dielectric layer is disposed on the lower dielectric layer and the lower metal layer. A via plug, a bottom electrode, and a magnetic tunnel junction are disposed in the dielectric layer, and the via plug is electrically connected to the lower metal layer. The bottom electrode is disposed on the via plug and the magnetic tunnel junction is disposed on the bottom electrode. An upper dielectric layer is disposed on the dielectric layer and the magnetic tunnel junction. An upper via plug and an upper metal layer are disposed in the upper dielectric layer, wherein the upper via plug is electrically connected to the magnetic tunnel junction.

In an embodiment of the disclosure, an upper surface of the magnetic tunnel junction is coplanar with an upper surface of the dielectric layer, and a lower surface of the via plug is coplanar with a lower surface of the dielectric layer.

In an embodiment of the disclosure, a thickness of the bottom electrode is 550 angstroms to 600 angstroms.

A forming method of a magnetoresistive random access memory includes the following operation. A lower metal layer and a lower dielectric layer are formed on a semiconductor substrate. The lower metal layer is disposed in the lower dielectric layer. A via plug, a bottom electrode, and a magnetic tunnel junction are formed on the lower metal layer in sequence. The via plug is electrically connected to the lower metal layer. The bottom electrode is disposed on the via plug, and the magnetic tunnel junction is disposed on the bottom electrode. A dielectric layer is formed on the lower dielectric layer and the lower metal layer, and the via plug, the bottom electrode, and the magnetic tunnel junction are covered. The dielectric layer is etched to expose an upper surface of the magnetic tunnel junction. An upper dielectric layer is formed on the dielectric layer and the magnetic tunnel junction. An upper via plug and an upper metal layer are formed in the upper dielectric layer. The upper via plug is electrically connected to the magnetic tunnel junction.

In an embodiment of the disclosure, the upper surface of the magnetic tunnel junction is coplanar with an upper surface of the dielectric layer, and a lower surface of the via plug is coplanar with a lower surface of the dielectric layer.

In an embodiment of the disclosure, a thickness of the bottom electrode is 550 angstroms to 600 angstroms.

A magnetoresistive random access memory includes the following components. A lower metal layer and a lower dielectric layer are disposed on a semiconductor substrate, and the lower metal layer is disposed in the lower dielectric layer. A dielectric layer is disposed on the lower dielectric layer and the lower metal layer. A via plug, a magnetic tunnel junction and a cap layer are disposed in the dielectric layer, and the via plug is electrically connected to the lower metal layer. The magnetic tunnel junction is disposed on the via plug and the cap layer is disposed on the magnetic tunnel junction. An upper dielectric layer is disposed on the dielectric layer and the cap layer. An upper via plug and an upper metal layer are disposed in the upper dielectric layer, wherein the upper via plug is electrically connected to the cap layer.

In an embodiment of the disclosure, an upper surface of the cap layer is coplanar with an upper surface of the dielectric layer, and a lower surface of the via plug is coplanar with a lower surface of the dielectric layer.

In an embodiment of the disclosure, a thickness of the cap layer is 350 angstroms to 400 angstroms.

A forming method of a magnetoresistive random access memory includes the following operation. A lower metal layer and a lower dielectric layer are formed on a semiconductor substrate. The lower metal layer is disposed in the lower dielectric layer. A via plug, a magnetic tunnel junction, and a cap layer are formed on the lower metal layer in sequence. The via plug is electrically connected to the lower metal layer. The magnetic tunnel junction is disposed on the via plug, and the cap layer is disposed on the magnetic tunnel junction. A dielectric layer is formed on the lower dielectric layer and the lower metal layer, and the via plug, the magnetic tunnel junction, and the cap layer are covered. The dielectric layer is etched to expose an upper surface of the cap layer. An upper dielectric layer is formed on the dielectric layer and the cap layer. An upper via plug and an upper metal layer are formed in the upper dielectric layer. The upper via plug is electrically connected to the cap layer.

In an embodiment of the disclosure, the upper surface of the cap layer is coplanar with an upper surface of the dielectric layer, and a lower surface of the via plug is coplanar with a lower surface of the dielectric layer.

In an embodiment of the disclosure, a thickness of the cap layer is 350 angstroms to 400 angstroms.

Based on the above, by forming an additional metal layer on the magnetic tunnel junction through this disclosure, the etching depths required for the upper via plugs in the magnetoresistive random access memory (MRAM) region and other device regions may be close or even the same. This reduces the need for excessive etching and resolves issues such as the abnormal profile of the upper via plugs in the MRAM region and the open phenomenon of the upper via plugs in other device regions. Consequently, the electrical performance of the integrated circuit is maintained within the desired range, thereby improving the overall yield of the wafer.

Moreover, by forming a bottom electrode under the magnetic tunnel junction through this disclosure, the etching depths required for the upper via plugs in the magnetoresistive random access memory (MRAM) region and other device regions may be close or even the same. This reduces the need for excessive etching and resolves issues such as the abnormal profile of the upper via plugs in the MRAM region and the open phenomenon of the upper via plugs in other device regions. Consequently, the electrical performance of the integrated circuit is maintained within the desired range, thereby improving the overall yield of the wafer.

Furthermore, by forming a cap layer on the magnetic tunnel junction through this disclosure, the etching depths required for the upper via plugs in the magnetoresistive random access memory (MRAM) region and other device regions may be close or even the same. This reduces the need for excessive etching and resolves issues such as the abnormal profile of the upper via plugs in the MRAM region and the open phenomenon of the upper via plugs in other device regions. Consequently, the electrical performance of the integrated circuit is maintained within the desired range, thereby improving the overall yield of the wafer.

### BRIEF DESCRIPTION OF THE DRAWINGS

FIG. 1 is a cross-sectional diagram of a magnetoresistive random access memory according to an embodiment of the disclosure.

FIG. 2A to FIG. 2C are cross-sectional diagrams of the manufacturing process of a magnetoresistive random access memory according to an embodiment of the disclosure.

FIG. 3 is a cross-sectional diagram of a magnetoresistive random access memory according to another embodiment of the disclosure.

FIG. 4A to FIG. 4B are cross-sectional diagrams of the manufacturing process of a magnetoresistive random access memory according to another embodiment of the disclosure.

FIG. 5 is a cross-sectional diagram of a magnetoresistive random access memory according to another embodiment of the disclosure.

FIG. 6A to FIG. 6B are cross-sectional diagrams of the manufacturing process of a magnetoresistive random access memory according to another embodiment of the disclosure.

### DETAILED DESCRIPTION OF DISCLOSED EMBODIMENTS

The following examples are described in detail with the accompanying drawings, but the provided examples are not intended to limit the scope of the disclosure. In order to facilitate understanding, the same components in the following description are described with the same symbols. In addition, the drawings are for illustrative purposes only and are not drawn in full scale. In fact, the dimensions of the various features may be arbitrarily increased or reduced for clarity of discussion.

As mentioned in the description of related art, since the magnetoresistive random access memory is disposed in the BEOL process, it may be readily integrable with the manufacturing processes of other semiconductor devices, forming a multifunctional and highly efficient integrated circuit.

In order to better understand the advantages of the disclosure, the following figures illustrate the magnetoresistive random access memory of the disclosure side by side with the logic device. However, the application of the disclosure is not limited thereto. The magnetoresistive random access memory of the disclosure may be used together with other semiconductor devices.

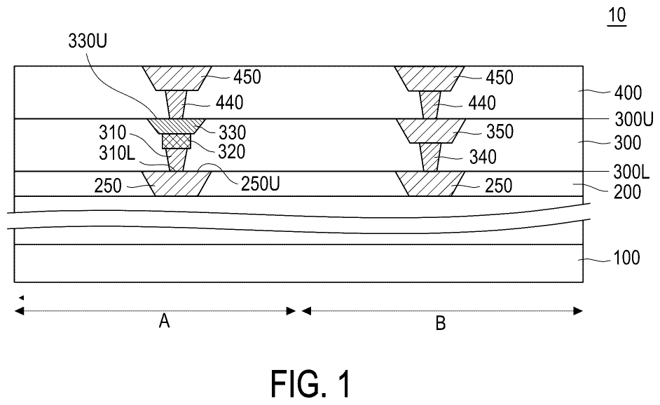

FIG. 1 is a cross-sectional diagram of a magnetoresistive random access memory according to an embodiment of the disclosure.

Firstly, please refer to the integrated circuit 10 shown in FIG. 1, which includes a magnetoresistive random access memory region A and a logic device region B.

In order to focus on the magnetoresistive random access memory in the BEOL process of the disclosure, the figure omits the logic devices disposed in/on the semiconductor substrate 100 and the first half portion of the metal interconnect layered structure disposed on the semiconductor substrate 100. The first half portion of the metal interconnect layered structure includes one or more interlayer dielectric layers. The first interlayer dielectric layer includes contact plugs that are in direct contact with the logic devices. The other interlayer dielectric layers include via plugs, metal conductive lines, and various other components.

In the BEOL process described later, a magnetoresistive random access memory is formed in a metal interconnect layered structure.

Continue referring to FIG. 1, the lower metal layer 250 and the lower dielectric layer 200 are disposed on the semiconductor substrate 100, in which the lower metal layer 250 is disposed in the lower dielectric layer 200. Between the semiconductor substrate 100 and the lower metal layer 250 and the lower dielectric layer 200, various semiconductor devices, such as logic devices, not shown in the diagram, are included, which are disposed on the semiconductor substrate 100. Additionally, the first half portion of the metal interconnect layered structure disposed on the semiconductor substrate 100 is also included.

The aforementioned lower metal layer 250 may include multiple layers, and its material or size may be adjusted based on the size or characteristics of components above and below the layer, such as contact plugs or via plugs.

Continue referring to FIG. 1, a dielectric layer 300 is disposed on the lower dielectric layer 220 and the lower metal layer 250.

Next, the following sections are divided as magnetoresistive random access memory region A and logic device region B for further description.

(Magnetoresistive random access memory region A)

The magnetoresistive random access memory region A includes a via plug 310, a magnetic tunnel junction 320, and an additional metal layer 330 disposed in the dielectric layer 300. The via plug 310 is electrically connected to the lower metal layer 250, the magnetic tunnel junction 320 is disposed on the via plug 310, and the additional metal layer 330 is disposed on the magnetic tunnel junction 320.

The magnetic tunnel junction 320 includes a multilayer structure, such as a bottom electrode, a magnetic memory body, an upper cap layer, and an upper electrode, but not limited thereto. The magnetic tunnel junction 320 may also include other materials and structures that serve as the magnetic tunnel junction. For the sake of simplicity and clarity, the multilayer structure is not shown in the figures of this application.

Due to the existence of the additional metal layer 330 in the magnetoresistive random access memory region A, the upper surface 330U of the additional metal layer 330 may be coplanar with the upper surface 300U of the dielectric layer 300, and the lower surface 310L of the via plug 310 may be coplanar with the lower surface 300L of the dielectric layer 300.

The thickness of the additional metal layer 330 is adjusted according to the purpose of making the upper surface 330U of the additional metal layer 330 coplanar with the upper surface 300U of the dielectric layer 300.

The thickness of the additional metal layer 330 is about 550 angstroms to 600 angstroms, more preferably about 580 angstroms to 600 angstroms, and most preferably about 590 angstroms to 600 angstroms.

The additional metal layer 330 may include tantalum, tantalum nitride, titanium, copper, tungsten, aluminum, or some other suitable conductive material. For example, tantalum or tantalum nitride is used.

This additional metal layer 330 may be a bit line.

The additional metal layer 330 may be formed into various shapes as required, such as a trapezoid with a wide top and a narrow bottom, to provide more process window for subsequent manufacturing of the upper via plug 440.

(Logic device region B)

The logic device region B includes a via plug 340 and a metal layer 350 disposed in the dielectric layer 300. The via plug 340 is electrically connected to the lower metal layer 250, and the metal layer 350 is disposed on the via plug 340.

Furthermore, an upper dielectric layer 400 is disposed on the dielectric layer 300, the additional metal layer 330, and the metal layer 350. An upper via plug 440 and an upper metal layer 450 are disposed in the upper dielectric layer 400. The upper via plug 440 is electrically connected to the additional metal layer 330 and the metal layer 350.

The above description order of the structure is not necessarily equal to the order in which the components are formed, that is, the order in which the above components are formed is not limited to the above described order.

In conventional technology, the magnetoresistive random access memory region A does not have an additional metal layer 330. Therefore, the required via depths for the via plugs between different devices are often different. This discrepancy results in uneven etch profiles after etching, and in some cases, excessive etching may cause the open issue, etc. These process-related issues may negatively impact the electrical properties and yield of the integrated circuits.

More specifically, since the magnetoresistive random access memory region A does not have an additional metal layer 330, the upper via plug 440 in the magnetoresistive random access memory region A requires a greater depth compared to the upper via plug 440 in the logic device region B. Consequently, excessive etching is necessary to meet the aforementioned requirements. However, the execution of such excessive etching often results in abnormal profiles of the upper via plug 440 in the magnetoresistive random access memory region A. Additionally, this excessive etching may cause the upper via plug 440 in the logic device region B to exhibit the open phenomenon.

However, by forming an additional metal layer 330 on the magnetic tunnel junction 320 through this disclosure, the etching depths required for the upper via plugs 440 in the magnetoresistive random access memory (MRAM) region A and the logic device region B may be close or even the same. This reduces the need for excessive etching and resolves issues such as the abnormal profile of the upper via plug 440 in the MRAM region A and the open phenomenon of the upper via plug 440 in the logic device region B. Consequently, the electrical performance of the integrated circuit 10 is maintained within the desired range, thereby improving the overall yield of the wafer.

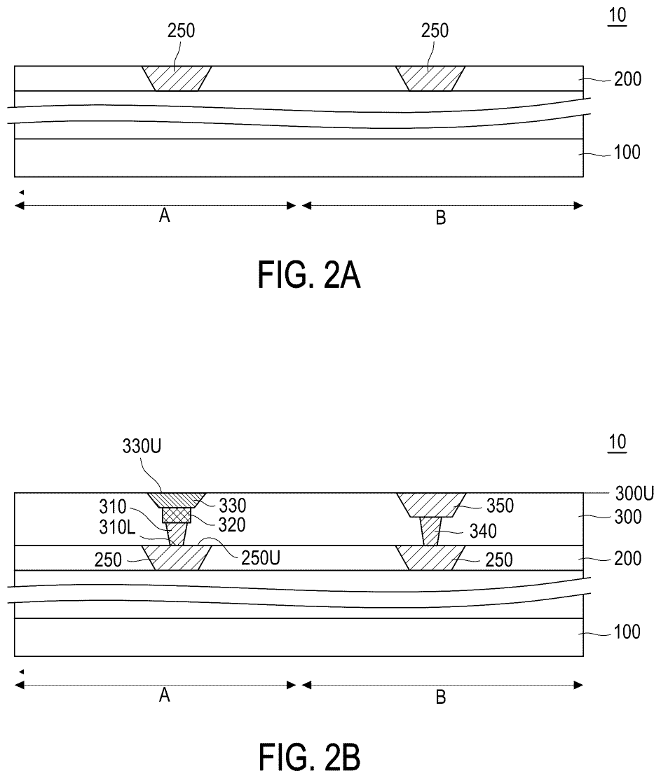

FIG. 2A to FIG. 2C are cross-sectional diagrams of the manufacturing process of a magnetoresistive random access memory according to an embodiment of the disclosure.

FIG. 2A to FIG. 2C are cross-sectional diagrams of a forming method of a magnetoresistive random access memory, and are also cross-sectional diagrams of a forming method of the integrated circuit 10 of FIG. 1.

As mentioned above, since the magnetoresistive random access memory is disposed in the BEOL process, it may be readily integrable with the manufacturing processes of other semiconductor devices, forming a multifunctional and highly efficient integrated circuit.

In order to better understand the advantages of the disclosure, the following cross-sectional diagrams of the manufacturing process illustrate the magnetoresistive random access memory of the disclosure side by side with the logic device. However, the application of the disclosure is not limited thereto. The magnetoresistive random access memory of the disclosure may be used together with other semiconductor devices.

Firstly, please refer to the integrated circuit 10 shown in FIG. 2A, which includes a magnetoresistive random access memory region A and a logic device region B.

As shown in FIG. 1, in order to focus on the magnetoresistive random access memory in the BEOL process of the disclosure, FIG. 2A to FIG. 2C omit the logic devices disposed in/on the semiconductor substrate 100 and the first half portion of the metal interconnect layered structure disposed on the semiconductor substrate 100. The first half portion of the metal interconnect layered structure (not shown) includes one or more interlayer dielectric layers. The first interlayer dielectric layer includes contact plugs that are in direct contact with the logic devices. The other interlayer dielectric layers include via plugs, metal conductive lines, and various other components.

In the first half portion of the omitted metal interconnect layered structure and the metal interconnect layered structure mainly described in the disclosure, the referred dielectric layer may include, for example, nitride (e.g., silicon nitride, silicon oxynitride), carbide (e.g., silicon carbide), oxides (e.g., silicon oxide), borosilicate glass (BSG), phosphoric silicate glass (PSG), borophosphosilicate glass (BPSG), low dielectric constant oxide (e.g., carbon-doped oxide, SiCOH), or some other suitable dielectric material. Various components such as contact plugs, via plugs, and metal conductive lines may include tantalum, titanium, copper, tungsten, aluminum, or some other suitable conductive material.

Moreover, the process for forming the first half portion of the omitted metal interconnect layered structure and the metal interconnect layered structure mainly described in the disclosure includes various steps, and the various steps include a deposition process (e.g., physical vapor deposition (PVD), chemical vapor deposition (CVD), plasma enhanced chemical vapor deposition (PE-CVD), atomic layer deposition (ALD), sputtering, etc.), a removal process (e.g., wet etching, dry etching, chemical mechanical planarization (CMP), etc.), and/or a patterning process (e.g., lithography/etching).

Continue referring to FIG. 2A, in the magnetoresistive random access memory region A and the logic device region B, a lower dielectric layer 200 and a lower metal layer 250 are formed on the semiconductor substrate 100, and the lower metal layer 250 is located in the lower dielectric layer 200 and is electrically connected to the front and rear conductive layers.

Referring to FIG. 2B, in the magnetoresistive random access memory region A, on the lower metal layer 250, the via plug 310, the magnetic tunnel junction 320, and the additional metal layer 330 are formed in sequence. The via plug 310 is electrically connected to the lower metal layer 250, the magnetic tunnel junction 320 is disposed on the via plug 310, and the additional metal layer 330 is disposed on the magnetic tunnel junction 320.

The magnetic tunnel junction 320 includes a multilayer structure, such as a bottom electrode, a magnetic memory body, an upper cap layer, and an upper electrode, but not limited thereto. The magnetic tunnel junction 320 may also include other materials and structures that serve as the magnetic tunnel junction. For the sake of simplicity and clarity, the multilayer structure is not shown in the figures of this application and may be formed in various ways.

Continue referring to FIG. 2B, in the magnetoresistive random access memory region A and the logic device region B, a dielectric layer 300 is formed on the lower dielectric layer 200 and the lower metal layer 250, and covers the via plug 310, the magnetic tunnel junction 320, and the additional metal layer 330 in the magnetoresistive random access memory region A. The dielectric layer 300 may be formed one or more times as required. For example, an insulating material such as silicon nitride may be initially formed on the sidewalls of the via plug 310, the magnetic tunneling junction 320, and the additional metal layer 330, followed by a comprehensive deposition of dielectric materials such as silicon dioxide, silicon oxynitride, borosilicate glass (BSG), phosphoric silicate glass (PSG), borophosphosilicate glass (BPSG), or SiCOH.

Next, chemical mechanical polishing (CMP) or other methods may be used as required to comprehensively planarize the dielectric layer 300, and the dielectric layer 300 is etched to expose the upper surface 330U of the additional metal layer 330 and the upper surface 250U of the lower metal layer 250 in the logic device region B.

The upper surface 330U of the additional metal layer 330 is coplanar with the upper surface 300U of the dielectric layer 300, and the lower surface 310L of the via plug 310 is coplanar with the lower surface 300L of the dielectric layer 300.

Next, as shown in FIG. 2B, a via plug 340 and a metal layer 350 are formed in the logic device region B.

Continue referring to FIG. 2B, the via plugs 310 in the magnetoresistive random access memory region A and the via plugs 340 in the logic device region B are both made of conductive materials, but may have different sizes and depths based on the different devices/components connected, and may be filled with different conductive materials to match with the requirements. For example, the via plug 310 in the magnetoresistive random access memory region A is made of tungsten, and the via plug 340 in the logic device region B is made of copper, but not limited thereto.

Referring to FIG. 2C, in the magnetoresistive random access memory region A and the logic device region B, an upper dielectric layer 400 is formed on the dielectric layer 300, the additional metal layer 330 and the metal layer 350, and an upper via plug 440 and an upper metal layer 450 are formed in the upper dielectric layer 400. The upper via plug 440 located in the magnetoresistive random access memory region A is electrically connected to the additional metal layer 330, and the upper via plug 440 located in the logic device region B is electrically connected to the metal layer 350 to complete the integrated circuit 10 as shown in FIG. 1.

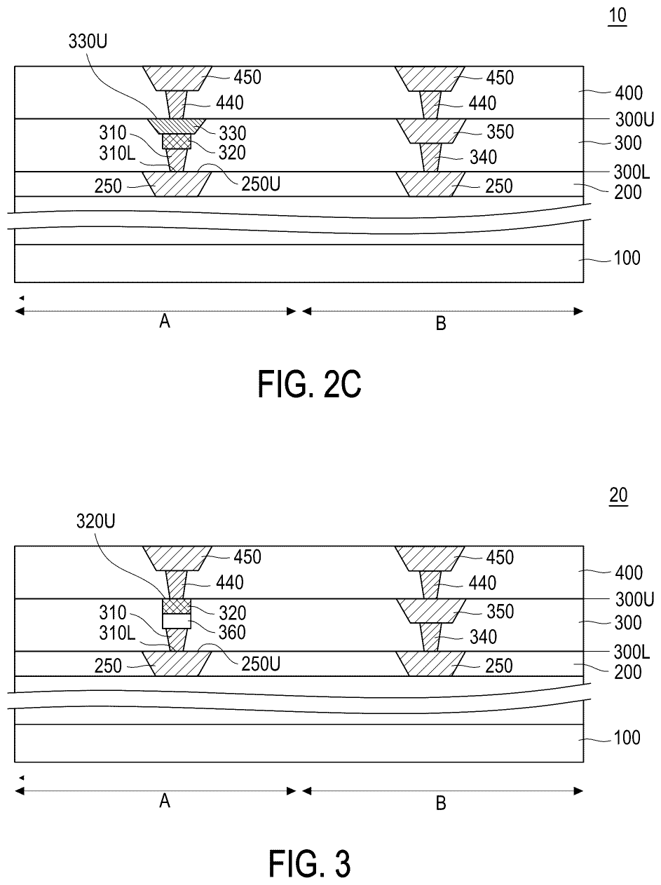

FIG. 3 is a cross-sectional diagram of a magnetoresistive random access memory according to another embodiment of the disclosure.

Since the integrated circuit 20 of FIG. 3 has some similar structures to the integrated circuit 10 of FIG. 1, the same components are labeled with the same symbols, and repeated descriptions are omitted. The following only describes the differences in components.

As shown in FIG. 3, the magnetoresistive random access memory region A includes a via plug 310, a bottom electrode 360, and a magnetic tunnel junction 320 disposed in the dielectric layer 300. The via plug 310 is electrically connected to the lower metal layer 250, the bottom electrode 360 is disposed on the via plug 310, and the magnetic tunnel junction 320 is disposed on the bottom electrode 360.

Due to the existence of the bottom electrode 330 in the magnetoresistive random access memory region A, the upper surface 320U of the magnetic tunnel junction 320 is coplanar with the upper surface 300U of the dielectric layer 300, and the lower surface 310L of the via plug 310 may be coplanar with the lower surface 300L of the dielectric layer 300.

It is worth noting that the thickness of the bottom electrode 360 is different from the bottom electrode of the conventional magnetic tunnel junction. Generally speaking, the bottom electrode 360 used in the disclosure is thicker than the bottom electrode layer of the conventional magnetic tunnel junction. The bottom electrode 360 is adjusted with the objective of making the upper surface 320U of the magnetic tunnel junction 320 coplanar with the upper surface 300U of the dielectric layer 300.

The thickness of the bottom electrode 360 is thickened from the conventional thickness of about 120 angstroms to 180 angstroms to about 550 angstroms to 600 angstroms, preferably about 580 angstroms to 600 angstroms, and most preferably about 590 angstroms to 600 angstroms.

The bottom electrode 360 includes tantalum, tantalum nitride, titanium, titanium nitride, copper, tungsten or some other suitable conductive material. For example, tantalum or tantalum nitride is used.

By forming the bottom electrode 360 under the magnetic tunnel junction 320 through this disclosure, the via depths required for the via plugs between different devices may be close or even the same. This reduces the need for excessive etching and resolves issues such as the abnormal profile of the upper via plug 440 in the MRAM region A and the open phenomenon of the upper via plug 440 in the logic device region B. Consequently, the electrical performance of the integrated circuit 20 is maintained within the desired range, thereby improving the overall yield of the wafer.

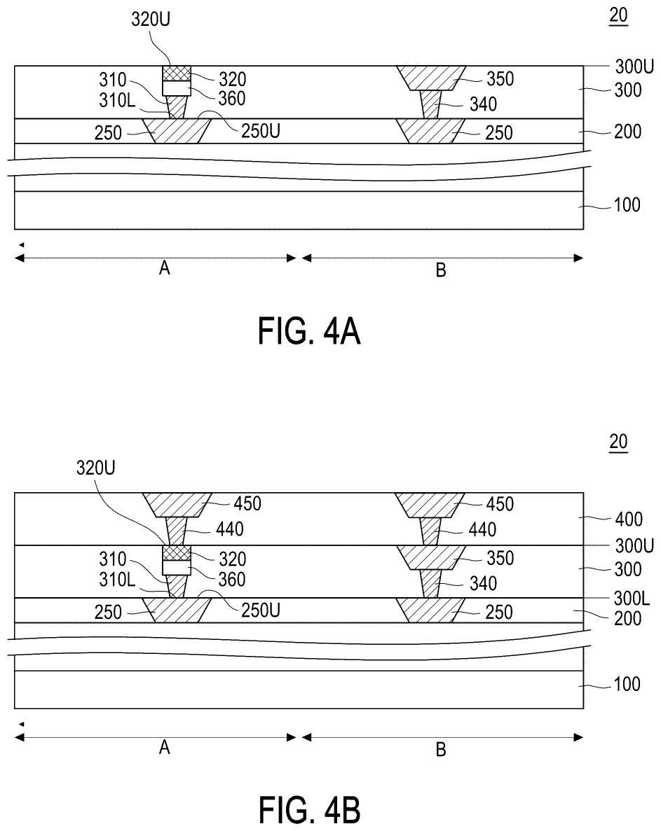

FIG. 4A to FIG. 4B are cross-sectional diagrams of the manufacturing process of a magnetoresistive random access memory according to another embodiment of the disclosure.

FIG. 4A to FIG. 4B are cross-sectional diagrams of a forming method of another magnetoresistive random access memory, and are also cross-sectional diagrams of a forming method of the integrated circuit 20 of FIG. 3.

Since the forming method of the integrated circuit 20 in FIG. 4A to FIG. 4B and the forming method of the integrated circuit 10 in FIG. 2A to FIG. 2C have similar processes and the same components, the same components are labeled with the same symbols, and repeated descriptions are omitted. The following only describes the differences in forming methods.

Firstly, referring to FIG. 4A, which corresponds to the aforementioned FIG. 2B, but in the magnetoresistive random access memory region A, on the lower metal layer 250, a via plug 310, a bottom electrode 360, and a magnetic tunnel junction 320 are sequentially formed. The via plug 310 is electrically connected to the lower metal layer 250, the bottom electrode 360 is disposed on the via plug 310, and the magnetic tunnel junction 320 is disposed on the bottom electrode 360.

The magnetic tunnel junction 320 includes a multilayer structure, such as a magnetic memory body, an upper cap layer, and an upper electrode, but not limited thereto. The magnetic tunnel junction 320 may also include other materials and structures that serve as the magnetic tunnel junction. For the sake of simplicity and clarity, the multilayer structure is not shown in the figures of this application and is formed in various ways.

The thickness of the bottom electrode 360 is thickened from the conventional thickness of about 120 angstroms to 180 angstroms to about 550 angstroms to 600 angstroms, preferably about 580 angstroms to 600 angstroms, and most preferably about 590 angstroms to 600 angstroms.

The bottom electrode 360 may include tantalum, tantalum nitride, platinum, titanium, copper, tungsten, aluminum or some other suitable conductive material. For example, tantalum nitride or platinum is used.

Continue referring to FIG. 4A, in the magnetoresistive random access memory region A and the logic device region B, a dielectric layer 300 is formed on the lower dielectric layer 200 and the lower metal layer 250, and covers the via plug 310, the bottom electrode 360, and the magnetic tunnel junction 320 in the magnetoresistive random access memory region A. The dielectric layer 300 may be formed one or more times as required. For example, an insulating material such as silicon nitride may be initially formed on the sidewalls of the via plug 310, the bottom electrode 360, and the magnetic tunneling junction 320, followed by a comprehensive deposition of dielectric materials such as silicon dioxide, silicon oxynitride, borosilicate glass (BSG), phosphoric silicate glass (PSG), borophosphosilicate glass (BPSG), or SiCOH.

Next, chemical mechanical polishing (CMP) or other methods may be used as required to comprehensively planarize the dielectric layer 300, and the dielectric layer 300 is etched to expose the upper surface 320U of the magnetic tunnel junction 320 and the upper surface 250U of the lower metal layer 250 in the logic device region B.

The upper surface 320U of the magnetic tunnel junction 320 is coplanar with the upper surface 300U of the dielectric layer 300, and the lower surface 310L of the via plug 310 is coplanar with the lower surface 300L of the dielectric layer 300.

Next, as shown in FIG. 4A, a via plug 340 and a metal layer 350 are formed in the logic device region B.

Continue referring to FIG. 4A, the via plugs 310 in the magnetoresistive random access memory region A and the via plugs 340 in the logic device region B are both made of conductive materials, but may have different sizes and depths based on the different devices/components connected, and may be filled with different conductive materials to match with the requirements. For example, the via plug 310 in the magnetoresistive random access memory region A is made of tungsten, and the via plug 340 in the logic device region B is made of copper, but not limited thereto.

Referring to FIG. 4B, which corresponds to the aforementioned FIG. 2C, but in the magnetoresistive random access memory region A and the logic device region B, an upper dielectric layer 400 is formed on the dielectric layer 300, the magnetic tunnel junction 320 and the metal layer 350, and an upper via plug 440 and an upper metal layer 450 are formed in the upper dielectric layer 400. The upper via plug 440 located in the magnetoresistive random access memory region A is electrically connected to the magnetic tunnel junction 320, and the upper via plug 440 located in the logic device region B is electrically connected to the metal layer 350 to complete the integrated circuit 20 as shown in FIG. 3.

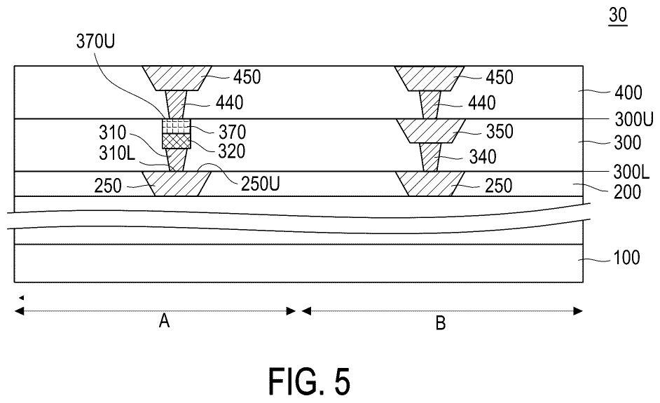

FIG. 5 is a cross-sectional diagram of a magnetoresistive random access memory according to another embodiment of the disclosure.

Since the integrated circuit 30 of FIG. 5 has some similar structures to the integrated circuit 10 of FIG. 1, the same components are labeled with the same symbols, and repeated descriptions are omitted. The following only describes the differences in components.

As shown in FIG. 5, the magnetoresistive random access memory region A includes a via plug 310, a magnetic tunnel junction 320, and a cap layer 370 disposed in the dielectric layer 300. The via plug 310 is electrically connected to the lower metal layer 250, the magnetic tunnel junction 320 is disposed on the via plug 310, and the cap layer 370 is disposed on the magnetic tunnel junction 320.

Due to the existence of the cap layer 370 in the magnetoresistive random access memory region A, the upper surface 370U of the cap layer 370 is coplanar with the upper surface 300U of the dielectric layer 300, and the lower surface 310L of the via plug 310 may be coplanar with the lower surface 300L of the dielectric layer 300.

It is worth noting that the thickness of the cap layer 370 is different from the cap layer of the conventional magnetic tunnel junction. Generally speaking, the cap layer 370 used in the disclosure is thicker than the cap layer of the conventional magnetic tunnel junction. The cap layer 370 is adjusted with the objective of making the upper surface 370U of the cap layer 370 coplanar with the upper surface 300U of the dielectric layer 300.

The thickness of the cap layer 370 is thickened from the conventional thickness of about 80 angstroms to 120 angstroms to about 350 angstroms to 400 angstroms, preferably about 380 angstroms to 400 angstroms, and most preferably about 390 angstroms to 400 angstroms. The cap layer 370 includes materials such as tantalum.

By forming the cap layer 370 on the magnetic tunnel junction 320 through this disclosure, the via depths required for the via plugs between different devices may be close or even the same. This reduces the need for excessive etching and resolves issues such as the abnormal profile of the upper via plug 440 in the MRAM region A and the open phenomenon of the upper via plug 440 in the logic device region B. Consequently, the electrical performance of the integrated circuit 20 is maintained within the desired range, thereby improving the overall yield of the wafer.

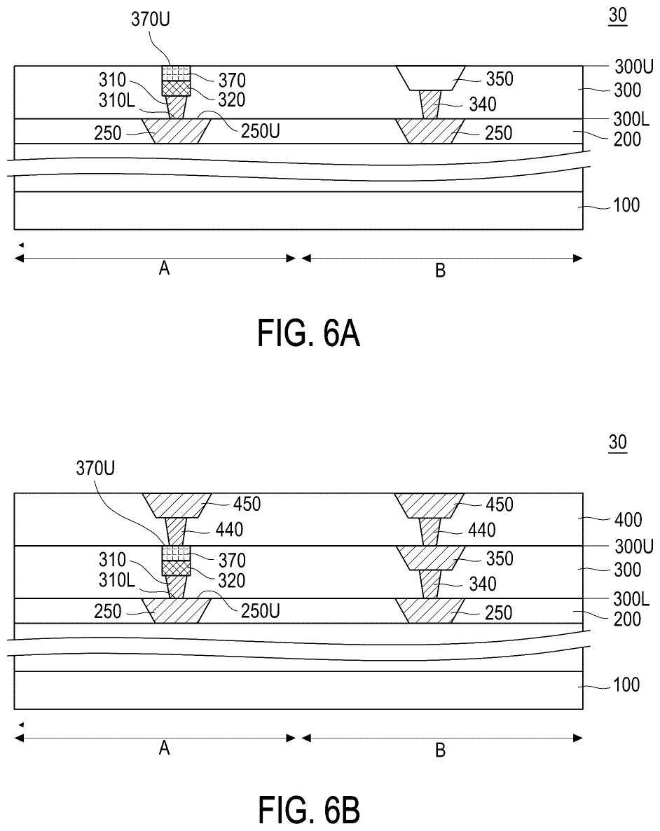

FIG. 6A to FIG. 6B are cross-sectional diagrams of the manufacturing process of a magnetoresistive random access memory according to another embodiment of the disclosure.

FIG. 6A to FIG. 6B are cross-sectional diagrams of a forming method of another magnetoresistive random access memory, and are also cross-sectional diagrams of a forming method of the integrated circuit 30 of FIG. 5.

Since the forming method of the integrated circuit 30 in FIG. 6A to FIG. 6B and the forming method of the integrated circuit 10 in FIG. 2A to FIG. 2C have similar processes and the same components, the same components are labeled with the same symbols, and repeated descriptions are omitted. The following only describes the differences in forming methods.

Firstly, referring to FIG. 6A, which corresponds to the aforementioned FIG. 2B, but in the magnetoresistive random access memory region A, on the lower metal layer 250, the via plug 310, the magnetic tunnel junction 320, and the cap layer 370 are formed in sequence. The via plug 310 is electrically connected to the lower metal layer 250, the magnetic tunnel junction 320 is disposed on the via plug 310, and the cap layer 370 is disposed on the magnetic tunnel junction 320.

The magnetic tunnel junction 320 includes a multilayer structure, such as a bottom electrode and a magnetic memory body, but not limited thereto. The magnetic tunnel junction 320 may also include other materials and structures that serve as the magnetic tunnel junction. For the sake of simplicity and clarity, the multilayer structure is not shown in the figures of this application and may be formed in various ways.

The thickness of the cap layer 370 is thickened from the conventional thickness of about 80 angstroms to 120 angstroms to about 350 angstroms to 400 angstroms, preferably about 380 angstroms to 400 angstroms, and most preferably about 390 angstroms to 400 angstroms.

The cap layer 370 includes materials such as tantalum.

Continue referring to FIG. 6A, in the magnetoresistive random access memory region A and the logic device region B, a dielectric layer 300 is formed on the lower dielectric layer 200 and the lower metal layer 250, and covers the via plug 310, the magnetic tunnel junction 320, and the cap layer 370 in the magnetoresistive random access memory region A. The dielectric layer 300 may be formed one or more times as required. For example, an insulating material such as silicon nitride may be initially formed on the sidewalls of the via plug 310, the magnetic tunneling junction 320, and the cap layer 370, followed by a comprehensive deposition of dielectric materials such as silicon dioxide, silicon oxynitride, borosilicate glass (BSG), phosphoric silicate glass (PSG), borophosphosilicate glass (BPSG), or SiCOH.

Next, chemical mechanical polishing (CMP) or other methods may be used as required to comprehensively planarize the dielectric layer 300, and the dielectric layer 300 is etched to expose the upper surface 370U of the cap layer 370 and the upper surface 250U of the lower metal layer 250 in the logic device region B.

The upper surface 370U of the cap layer 370 is coplanar with the upper surface 300U of the dielectric layer 300, and the lower surface 310L of the via plug 310 is coplanar with the lower surface 300L of the dielectric layer 300.

Next, as shown in FIG. 6A, a via plug 340 and a metal layer 350 are formed in the logic device region B.

Continue referring to FIG. 6A, the via plugs 310 in the magnetoresistive random access memory region A and the via plugs 340 in the logic device region B are both made of conductive materials, but may have different sizes and depths based on the different devices/components connected, and may be filled with different conductive materials to match with the requirements. For example, the via plug 310 in the magnetoresistive random access memory region A is made of tungsten, and the via plug 340 in the logic device region B is made of copper, but not limited thereto.

Referring to FIG. 6B, which corresponds to the aforementioned FIG. 2C, but in the magnetoresistive random access memory region A and the logic device region B, an upper dielectric layer 400 is formed on the dielectric layer 300, the cap layer 370 and the metal layer 350, and an upper via plug 440 and an upper metal layer 450 are formed in the upper dielectric layer 400. The upper via plug 440 located in the magnetoresistive random access memory region A is electrically connected to the cap layer 370, and the upper via plug 440 located in the logic device region B is electrically connected to the metal layer 350 to complete the integrated circuit 30 as shown in FIG. 5.

To sum up, by forming an additional metal layer on the magnetic tunnel junction through this disclosure, the etching depths required for the upper via plugs in the magnetoresistive random access memory (MRAM) region and other device regions may be close or even the same. This reduces the need for excessive etching and resolves issues such as the abnormal profile of the upper via plugs in the MRAM region and the open phenomenon of the upper via plugs in other device regions. Consequently, the electrical performance of the integrated circuit is maintained within the desired range, thereby improving the overall yield of the wafer.

Moreover, by forming a bottom electrode under the magnetic tunnel junction through this disclosure, the etching depths required for the upper via plugs in the magnetoresistive random access memory (MRAM) region and other device regions may be close or even the same. This reduces the need for excessive etching and resolves issues such as the abnormal profile of the upper via plugs in the MRAM region and the open phenomenon of the upper via plugs in other device regions. Consequently, the electrical performance of the integrated circuit is maintained within the desired range, thereby improving the overall yield of the wafer.

Furthermore, by forming a cap layer on the magnetic tunnel junction through this disclosure, the etching depths required for the upper via plugs in the magnetoresistive random access memory (MRAM) region and other device regions may be close or even the same. This reduces the need for excessive etching and resolves issues such as the abnormal profile of the upper via plugs in the MRAM region and the open phenomenon of the upper via plugs in other device regions. Consequently, the electrical performance of the integrated circuit is maintained within the desired range, thereby improving the overall yield of the wafer.

5 Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A magnetoresistive random access memory, comprising:
a lower metal layer and a lower dielectric layer, disposed on a semiconductor substrate, wherein the lower metal layer is disposed in the lower dielectric layer;
a dielectric layer, disposed on the lower dielectric layer and the lower metal layer;
a via plug, a magnetic tunnel junction, and an additional metal layer, disposed in the dielectric layer, wherein the via plug is electrically connected to the lower metal layer, the magnetic tunnel junction is disposed on the via plug and the additional metal layer is disposed on the magnetic tunnel junction;
an upper dielectric layer, disposed on the dielectric layer and the additional metal layer; and
an upper via plug and an upper metal layer, disposed in the upper dielectric layer, wherein the upper via plug is electrically connected to the additional metal layer.

2. The magnetoresistive random access memory according to claim 1, wherein an upper surface of the additional metal layer is coplanar with an upper surface of the dielectric layer, and a lower surface of the via plug is coplanar with a lower surface of the dielectric layer.

3. The magnetoresistive random access memory according to claim 1, wherein the additional metal layer is a bit line.

4. The magnetoresistive random access memory according to claim 1, wherein the additional metal layer is a trapezoid with a wide top and a narrow bottom.

5. The magnetoresistive random access memory according to claim 1, wherein a thickness of the additional metal layer is 550 angstroms to 600 angstroms.

6. A forming method of a magnetoresistive random access memory, comprising:
forming a lower metal layer and a lower dielectric layer on a semiconductor substrate, wherein the lower metal layer is disposed in the lower dielectric layer;
forming a via plug, a magnetic tunnel junction, and an additional metal layer on the lower metal layer in sequence, wherein the via plug is electrically connected to the lower metal layer, the magnetic tunnel junction is disposed on the via plug, and the additional metal layer is disposed on the magnetic tunnel junction;
forming a dielectric layer on the lower dielectric layer and the lower metal layer, and covering the via plug, the magnetic tunnel junction, and the additional metal layer;
etching the dielectric layer to expose an upper surface of the additional metal layer;
forming an upper dielectric layer on the dielectric layer and the additional metal layer; and
forming an upper via plug and an upper metal layer in the upper dielectric layer, wherein the upper via plug is electrically connected to the additional metal layer.

7. The forming method of the magnetoresistive random access memory according to claim 6, wherein the upper surface of the additional metal layer is coplanar with an upper surface of the dielectric layer, and a lower surface of the via plug is coplanar with a lower surface of the dielectric layer.

8. The forming method of the magnetoresistive random access memory according to claim 6, wherein the additional metal layer is a bit line.

9. The forming method of the magnetoresistive random access memory according to claim 6, wherein the additional metal layer is a trapezoid with a wide top and a narrow bottom.

10. The forming method of the magnetoresistive random access memory according to claim 6, wherein a thickness of the additional metal layer is 550 angstroms to 600 angstroms.

11. A magnetoresistive random access memory, comprising:
A lower metal layer and a lower dielectric layer, disposed on a semiconductor substrate, wherein the lower metal layer is disposed in the lower dielectric layer;
a dielectric layer, disposed on the lower dielectric layer and the lower metal layer;
a via plug, a bottom electrode, and a magnetic tunnel junction, disposed in the dielectric layer, wherein the via plug is electrically connected to the lower metal layer, the bottom electrode is disposed on the via plug and the magnetic tunnel junction is disposed on the bottom electrode;
an upper dielectric layer, disposed on the dielectric layer and the magnetic tunnel junction; and
an upper via plug and an upper metal layer, disposed in the upper dielectric layer, wherein the upper via plug is electrically connected to the magnetic tunnel junction.

12. The magnetoresistive random access memory according to claim 11, wherein an upper surface of the magnetic tunnel junction is coplanar with an upper surface of the dielectric layer, and a lower surface of the via plug is coplanar with a lower surface of the dielectric layer.

13. The magnetoresistive random access memory according to claim 11, wherein a thickness of the bottom electrode is 550 angstroms to 600 angstroms.

14. A forming method of a magnetoresistive random access memory, comprising:
forming a lower metal layer and a lower dielectric layer on a semiconductor substrate, wherein the lower metal layer is disposed in the lower dielectric layer;
forming a via plug, a bottom electrode, and a magnetic tunnel junction on the lower metal layer in sequence, wherein the via plug is electrically connected to the lower metal layer, the bottom electrode is disposed on the via plug and the magnetic tunnel junction is disposed on the bottom electrode;
forming a dielectric layer on the lower dielectric layer and the lower metal layer, and covering the via plug, the bottom electrode, and the magnetic tunnel junction;
etching the dielectric layer to expose an upper surface of the magnetic tunnel junction;
forming an upper dielectric layer on the dielectric layer and the magnetic tunnel junction; and
forming an upper via plug and an upper metal layer in the upper dielectric layer, wherein the upper via plug is electrically connected to the magnetic tunnel junction.

15. The forming method of the magnetoresistive random access memory according to claim 14, wherein the upper surface of the magnetic tunnel junction is coplanar with an upper surface of the dielectric layer, and a lower surface of the via plug is coplanar with a lower surface of the dielectric layer.

16. The forming method of the magnetoresistive random access memory according to claim 14, wherein a thickness of the bottom electrode is 550 angstroms to 600 angstroms.

17. A magnetoresistive random access memory, comprising:
a lower metal layer and a lower dielectric layer, disposed on a semiconductor substrate, wherein the lower metal layer is disposed in the lower dielectric layer;
a dielectric layer, disposed on the lower dielectric layer and the lower metal layer;
a via plug, a magnetic tunnel junction and a cap layer, disposed in the dielectric layer, wherein the via plug is electrically connected to the lower metal layer, the magnetic tunnel junction is disposed on the via plug and the cap layer is disposed on the magnetic tunnel junction;
an upper dielectric layer, disposed on the dielectric layer and the cap layer; and
an upper via plug and an upper metal layer, disposed in the upper dielectric layer, wherein the upper via plug is electrically connected to the cap layer.

18. The magnetoresistive random access memory according to claim 17, wherein an upper surface of the cap layer is coplanar with an upper surface of the dielectric layer, and a lower surface of the via plug is coplanar with a lower surface of the dielectric layer.

19. The magnetoresistive random access memory according to claim 17, wherein a thickness of the cap layer is 350 angstroms to 400 angstroms.

20. A forming method of a magnetoresistive random access memory, comprising:
forming a lower metal layer and a lower dielectric layer on a semiconductor substrate, wherein the lower metal layer is disposed in the lower dielectric layer;
forming a via plug, a magnetic tunnel junction, and a cap layer on the lower metal layer in sequence, wherein the via plug is electrically connected to the lower metal layer, the magnetic tunnel junction is disposed on the via plug, and the cap layer is disposed on the magnetic tunnel junction;
forming a dielectric layer on the lower dielectric layer and the lower metal layer, and covering the via plug, the magnetic tunnel junction, and the cap layer;
etching the dielectric layer to expose an upper surface of the cap layer;
forming an upper dielectric layer on the dielectric layer and the cap layer; and
forming an upper via plug and an upper metal layer in the upper dielectric layer, wherein the upper via plug is electrically connected to the cap layer.

21. The forming method of the magnetoresistive random access memory according to claim 20, wherein the upper surface of the cap layer is coplanar with an upper surface of the dielectric layer, and a lower surface of the via plug is coplanar with a lower surface of the dielectric layer.

22. The forming method of the magnetoresistive random access memory according to claim 20, wherein a thickness of the cap layer is 350 angstroms to 400 angstroms.
